(19) United States
(12) Patent Application Publication
(10) Pub. No.: US 2018/0048114 A1
(43) Pub. Date: Feb. 15, 2018

(54) EDGE-EMITTING SEMICONDUCTOR LASER AND METHOD FOR THE PRODUCTION THEREOF

(71) Applicant: OSRAM Opto Semiconductors GmbH, Regensburg (DE)

(72) Inventors: Alfred Lell, Maxhütte-Haidhof (DE); Harald König, Bernhardswald (DE); Adrian Stefan Avramescu, Regensburg (DE)

(21) Appl. No.: 15/559,725

(22) PCT Filed: Mar. 18, 2016
(86) PCT No.: PCT/EP2016/055937

§ 371 Date: Sep. 19, 2017

(30) Foreign Application Priority Data
Mar. 20, 2015 (DE) 10 2015 104 184.7

(51) Int. Cl. H01S 5/026

(52) U.S. Cl. CPC H01S 5/026; H01S 2304/00

(57) ABSTRACT

An edge-emitting semiconductor laser includes a semiconductor structure laterally bounded by first and second facets and having a central section and a first edge section, a layer sequence offset relative to the central section in the growth direction in the first edge section such that, in the first edge section, one of the cladding layers or one of the waveguide layers is arranged in the growth direction at a height of the active layer in the central section, the layer sequence includes an epitaxially grown additional layer arranged between the upper side and the lower cladding layer, the additional layer is not arranged between the upper side and the lower cladding layer in the central section, and the additional layer is electrically insulating or has doping with the opposite sign to the lower cladding layer.

### TECHNICAL FIELD

This disclosure relates to an edge-emitting semiconductor laser and a method of producing an edge-emitting semiconductor laser.

### BACKGROUND

It is known that the mirror facets in edge-emitting semiconductor lasers are exposed to high electrical, optical and thermal stresses. Absorption losses at the mirror facets may lead to heating of the mirror facets and ultimately to their thermal destruction.

It could therefore be helpful to provide an edge-emitting semiconductor laser, the mirror facets of which are less susceptible to thermal destruction.

### SUMMARY

We provide an edge-emitting semiconductor laser including a semiconductor structure having a substrate and a layer sequence arranged over an upper side of the substrate and having layers lying above one another along a growth direction, wherein a lower cladding layer, a lower waveguide layer, an active layer, an upper waveguide layer and an upper cladding layer follow one another in the layer sequence, the semiconductor structure is laterally bounded by a first facet and a second facet, the semiconductor structure has a central section and a first edge section adjacent to the first facet, the layer sequence is offset relative to the central section in the growth direction in the first edge section such that, in the first edge section, one of the cladding layers or one of the waveguide layers is arranged in the growth direction at a height of the active layer in the central section, the layer sequence includes an epitaxially grown additional layer arranged between the upper side of the substrate and the lower cladding layer at least in the first edge section, the additional layer is not arranged between the upper side of the substrate and the lower cladding layer in the central section, and the additional layer is electrically insulating or has doping with the opposite sign to the lower cladding layer.

We also provide a method of producing an edge-emitting semiconductor laser including providing a substrate having an upper side; arranging an additional layer on the upper side of the substrate by epitaxial growth; removing a part of the additional layer in a central section to form, on an upper side of the substrate, a surface having a different height in the central section than in a first edge section; depositing a layer sequence over the surface, wherein deposition of the layer sequence includes deposition of a lower cladding layer, a lower waveguide layer, an active layer, an upper waveguide layer and an upper cladding layer, the additional layer is electrically insulating or has doping with the opposite sign to the lower cladding layer, a height difference of the surface between the central section and the first edge section is dimensioned such that, in the first edge section, one of the cladding layers or one of the waveguide layers is arranged at the height of the active layer in the central section; and fracturing the substrate and the layer sequence such that a first facet, to which the first edge section is adjacent, is formed.

### BRIEF DESCRIPTION OF THE DRAWINGS

FIG. 1 shows a schematic sectional side view of a semiconductor structure of an edge-emitting semiconductor laser according to a first example.

FIG. 2 shows a schematic sectional side view of a semiconductor structure of an edge-emitting semiconductor laser according to a second example.

FIG. 3 shows a schematic sectional side view of a semiconductor structure of an edge-emitting semiconductor laser according to a third example.

FIG. 4 shows a schematic sectional side view of a semiconductor structure of an edge-emitting semiconductor laser according to a fourth example.

FIG. 5 shows a schematic sectional side view of a semiconductor structure of an edge-emitting semiconductor laser according to a fifth example.

FIG. 6 shows a schematic sectional side view of a semiconductor structure of an edge-emitting semiconductor laser according to a sixth example.

FIG. 7 shows a schematic sectional side view of a semiconductor structure of an edge-emitting semiconductor laser according to a seventh example.

FIG. 8 shows a schematic sectional side view of a semiconductor structure of an edge-emitting semiconductor laser according to an eighth example.

### LIST OF REFERENCES

10 edge-emitting semiconductor laser
11 edge-emitting semiconductor laser
12 edge-emitting semiconductor laser
13 edge-emitting semiconductor laser
14 edge-emitting semiconductor laser
15 edge-emitting semiconductor laser
16 edge-emitting semiconductor laser
17 edge-emitting semiconductor laser
20 semiconductor structure
100 substrate
101 upper side
110 upper metallization
120 step
200 layer sequence
201 growth direction
210 lower cladding layer
220 lower waveguide layer
230 active layer
240 upper waveguide layer
250 upper cladding layer
260 additional layer
270 step
280 ramp
300 central section
400 first facet
410 first edge section
420 first transition section
430 first offset
440 width
500 second facet
510 second edge section
520 second transition section
530 second offset

### DETAILED DESCRIPTION

Our edge-emitting semiconductor laser comprises a semiconductor structure having a layer sequence that has layers lying above one another along a growth direction. The semiconductor structure is laterally bounded by a first facet and a second facet. The semiconductor structure has a central section and a first edge section adjacent to the first facet. The layer sequence is offset relative to the central section in the growth direction in the first edge section.

Because the layer sequence of the semiconductor structure of this edge-emitting semiconductor laser is offset relative to the central section in the first edge section, light excited in the semiconductor structure is guided in different layers of the layer sequence in the first edge section than in the central section. These other layers have a higher band gap so that absorption of light in the first edge section is impeded or entirely prevented. The first facet and the first edge section adjacent to the first facet, therefore, form a nonabsorbing mirror. This nonabsorbing mirror has only low mirror losses so that only minor heating of the first facet and the first edge section adjacent to the first facet occurs during operation of the edge-emitting semiconductor laser. In this edge-emitting semiconductor laser, there is therefore only a reduced risk of temperature-dependent ageing effects and thermal destruction.

A lower cladding layer, a lower waveguide layer, an active layer, an upper waveguide layer and an upper cladding layer follow one another in the layer sequence. In this case, in the first edge section, one of the cladding layers or one of the waveguide layers is arranged in the growth direction at the height of the active layer in the central section. The effect advantageously achieved by this is that light guided in the waveguide layers in the central section of the semiconductor structure is guided at least partially in one of the cladding layers in the first edge section so that the first facet and the first edge section, adjacent to the first facet, of the semiconductor structure form a nonabsorbing mirror.

The semiconductor structure may have a second edge section adjacent to the second facet. In this case, the layer sequence is offset relative to the central section in the growth direction in the second edge section. Advantageously, the second facet and the second edge section adjacent to the second facet of the semiconductor structure then also form a nonabsorbing mirror. This also reduces the risk of thermal destruction in the edge-emitting semiconductor laser in the region of the second facet.

The offset of the layer sequence in the second edge section may correspond to the offset of the layer sequence in the first edge section. In this way, the semiconductor structure of the edge-emitting semiconductor laser has a symmetrical configuration that can advantageously be produced particularly simply and economically.

The layer sequence lies higher in the growth direction in the first edge section than in the central section. The effect achieved in this way is that in the first edge section, a layer which, in the central section, is arranged below the active layer is adjacent to the active layer in the central section.

The semiconductor structure comprises a substrate. The layer sequence is arranged over an upper side of the substrate. The layer sequence comprises an additional layer arranged between the upper side of the substrate and the lower cladding layer at least in sections. This additional layer has a different height in the growth direction in the central section than in the first edge section. The height variation of the additional layer advantageously continues in the rest of the layer sequence arranged over the additional layer so that there is an offset between the first edge section and the central section in the layer sequence.

The additional layer is electrically insulating or has doping with the opposite sign to the lower cladding layer. The additional layer is not arranged between the upper side of the substrate and the lower cladding layer in the central section. The insulating additional layer may be configured as an undoped epitaxial layer, as a CVD diamond layer or as a dielectric layer, for example. Advantageously, this additional layer blocks a current path through the layer sequence in the first edge section of the semiconductor structure. No laser light is therefore excited in the first edge section of the semiconductor structure. In this way, possible absorption losses at the first facet and in the first edge section, adjacent to the first facet, of the semiconductor structure are advantageously reduced further.

The semiconductor structure may have a first transition section between the central section and the first edge section. In this case, the layer sequence continues continuously between the central section, the first transition section and the first edge section. Advantageously, the semiconductor structure can therefore be produced particularly simply.

The central section may lie at a distance of 0.1 μm to 100 μm from the first facet, preferably at a distance of 1 μm to 20 μm. Advantageously, we found such a distance to be particularly effective for the formation of a nonabsorbing mirror in the region of the first facet and the first edge section adjacent to the first facet.

A contact layer and an upper metallization may be arranged over the layer sequence. In this case, the upper metallization is arranged only over the central section and not over the first edge section. The effect advantageously achieved by this is that the semiconductor structure of the edge-emitting semiconductor laser is supplied with current during operation of the edge-emitting semiconductor laser only in the central section, but not in the first edge section. No laser light is therefore excited in the first edge section of the semiconductor structure so that possible absorption losses at the first facet and in the first edge section adjacent to the first facet are reduced further.

A method of producing an edge-emitting semiconductor laser comprises steps of providing a substrate having an upper side, applying, on the upper side of the substrate, a surface having a different height in a central section than in a first edge section, depositing a layer sequence over the surface, and fracturing the substrate and the layer sequence such that a first facet to which the first edge section is adjacent is formed.

The edge-emitting semiconductor laser that may be obtained by this method has a semiconductor structure, the layer sequence of which is offset in the growth direction in a first edge section, which is adjacent to the first facet, relative to the central section. In this way, the first facet, and the first edge section, adjacent to the first facet, of the semiconductor structure of this edge-emitting semiconductor laser act as a nonabsorbing mirror. This nonabsorbing mirror offers the advantages that no absorption losses, or only minor absorption losses, occur in the region of the nonabsorbing mirror so that no heating, or only minor heating, of the first facet and the first edge section adjacent to the first facet occur. In this way, furthermore, only minor ageing effects occur in the region of the first facet so that the risk of thermal destruction of the first facet of the semiconductor structure of the edge-emitting semiconductor laser which can be obtained by the method is reduced.

The method of producing the edge-emitting semiconductor laser advantageously makes do without diffusion processes or implantation processes so that it can be carried out simply and in a controlled way. This leads to good reproducibility, which can make a high yield possible during production. The method furthermore advantageously requires no processing operations at high temperature so that damage associated with high-temperature processes to an active layer of the semiconductor structure of the edge-emitting semiconductor laser which can be obtained by the method is avoided. Damage associated with high-temperature processes to electrical contacts of the edge-emitting semiconductor laser is also avoided so that an undesired increase in the operating voltage of the edge-emitting semiconductor laser which can be obtained by the method is also avoided. Other reductions caused by high-temperature processes and/or implantation processes or diffusion processes of the lifetime to be expected for the edge-emitting semiconductor laser are also advantageously avoided.

Application of the surface comprises steps of arranging an additional layer on the upper side of the substrate and of removing a part of the additional layer. In this method, a height, varying over the upper side of the substrate, of the additional layer is carried over into the layer sequence deposited over the additional layer so that there is an offset in the growth direction between the first edge section and the central section in the semiconductor structure of the edge-emitting semiconductor laser which can be obtained by the method.

Removal of the additional layer may be carried out by an etching method. The etching method may, for example, be a dry etching method. Since removal of the substrate or the additional layer is carried out before the growth of the layer sequence, such an etching method advantageously leads to no damage, or only minor damage, of an active layer of the layer sequence of the semiconductor laser which can be obtained by the method.

Deposition of the layer sequence comprises deposition of a lower cladding layer, a lower waveguide layer, an active layer, an upper waveguide layer and an upper cladding layer. In this case, the height difference of the surface between the central section and the first edge section is dimensioned such that, in the first edge section, one of the cladding layers or one of the waveguide layers is arranged at the height of the active layer in the central section. The effect advantageously achieved by this is that light guided in the waveguide layers in the central section of the semiconductor structure is guided at least partially in one of the cladding layers in the first edge section so that the first facet and the first edge section act as a nonabsorbing mirror.

The above-described properties, features and advantages, as well as the way in which they are achieved, will become more clearly and readily comprehensible in conjunction with the following description of the examples, which will be explained in more detail in connection with the drawings.

FIG. 1 shows a schematic sectional side view of a semiconductor structure 20 of an edge-emitting semiconductor laser 10. The edge-emitting semiconductor laser 10 may also be referred to as a diode laser. The edge-emitting semiconductor laser 10 may, for example, be provided for emission of light in a wavelength in the UV spectral range, in the visible spectral range or in the infrared spectral range. The semiconductor structure 20 of the edge-emitting semiconductor laser 10 may, for example, be based on an AlInGaN, an AlGaAs or an InGaAlP material system.

The semiconductor structure 20 of the edge-emitting semiconductor laser 10 has a substrate 100 and a layer sequence 200 grown epitaxially over an upper side 101 of the substrate 100. The layer sequence comprises a multiplicity of layers, which lie above one another along a growth direction 201. The growth direction 201 is oriented perpendicularly to the upper side 101 of the substrate 100.

The semiconductor structure 20 is laterally bounded by a first facet 400 and by a second facet 500, lying opposite the first facet 400. The first facet 400 and the second facet 500 are oriented substantially parallel to the growth direction 201. The first facet 400 and the second facet 500 have been formed after epitaxial growth of the layer sequence 200 by fracturing the semiconductor structure 20.

A resonator of the edge-emitting semiconductor laser 10 extends between the first facet 400 and the second facet 500. The first facet 400 forms a light-emitting laser facet of the edge-emitting semiconductor laser 10. During operation of the edge-emitting semiconductor laser 10, laser light is emitted at the first facet 400 in a direction perpendicular to the first facet 400.

The semiconductor structure 20 of the edge-emitting semiconductor laser 10 has a central section 300 and a first edge section 410 adjacent to the first facet 400. The central section 300 and the first edge section 410 are arranged next to one another in a direction parallel to the upper side 101 of the substrate 100, and are directly adjacent to one another in the semiconductor structure 20 of the edge-emitting semiconductor laser 10.

The first edge section 410 has a width of 440, measured from the first facet 400 and in a direction perpendicular to the first facet 400. The width 440 may, for example, be 0.1 μm to 100 μm, in particular, for example, 1 μm to 20 μm. This means that, in the semiconductor structure 20 of the edge-emitting semiconductor laser 10, the central section 300 lies at a distance from the first facet 400 which corresponds to the width 440 of the first edge section 410.

In the first edge section 410, the layer sequence 200 of the semiconductor structure 20 of the edge-emitting semiconductor laser 10 is offset in the growth direction 201 relative to the central section 300. In this case, the layers of the layer sequence 200 lie higher in the growth direction 201 in the central section 300 of the semiconductor structure 20 than in the first edge section 410. An essentially step-like first offset 430 in the layer sequence 200 is therefore formed between the central section 300 and the first edge section 410.

A step 120 is configured on the upper side 101 of the substrate 100 of the semiconductor structure 20. In this case, the upper side 101 of the substrate 100 lies lower in the growth direction 201 in the first edge section 410 than in the central section 300 so that the step 120 is formed at the boundary between the edge section 410 and the central section 300. The different height in the growth direction 201 of the upper side 101 of the substrate 100 in the central section 300 and in the first edge section 410 has been carried over during epitaxial growth of the layer sequence 200 onto the upper side 101 of the substrate 100 into the layer sequence 200 so that the first offset 430 has been formed.

The step 120 on the upper side 101 of the substrate 100 may, for example, have been formed by a part of the substrate 100 having been removed in the first edge section 410 before the epitaxial growth of the layer sequence 200. The removal of the part of the substrate 100 may, for example, have been carried out by etching, in particular, for example, by a dry etching method.

In the example of the semiconductor structure 20 of the edge-emitting semiconductor laser 10 as shown in FIG. 1, the layer sequence 200 comprises a lower cladding layer 210, a lower waveguide layer 220, an active layer 230, an upper waveguide layer 240 and an upper cladding layer 250, which follow one another in the growth direction 201 in the order stated. The lower cladding layer 210 lies closest to the substrate 100, and may in particular be arranged directly on the upper side 101 of the substrate 100. The layer sequence 200 could, however, also comprise even further layers. In particular, further layers could be arranged between the substrate 100 and the lower cladding layer 210 and above the upper cladding layer 250.

The lower cladding layer 210 and the lower waveguide layer 220 of the layer sequence 200 have doping with a first sign, for example, n-doping. The upper waveguide layer 240 and the upper cladding layer 250 of the layer sequence 200 have doping with an opposite sign compared to the doping of the lower cladding layer 210 and the lower waveguide layer 220, for example, p-doping.

The lower cladding layer 210 and the upper cladding layer 250 of the layer sequence 200 comprise a first material. The lower waveguide layer 220 and the upper waveguide layer 240 comprise a second material. The material of the lower cladding layer 210 and the upper cladding layer 250 has a lower refractive index than the material of the lower waveguide layer 220 and the upper waveguide layer 240. The lower cladding layer 210 and the upper cladding layer 250 have an increased band gap compared to the waveguide layers 220, 240.

The active layer 230 of the layer sequence 200 may, for example, be configured as a quantum well or quantum film, or as a two-dimensional arrangement of quantum dots.

The first offset 430 in the layer sequence 200, between the first edge section 410 and the central section 300, is dimensioned such that, in the first edge section 410, the upper cladding layer 250 is arranged in the growth direction 201 at the height of the active layer 230 in the central section 300. As an alternative, it is possible to configure the first offset 430 such that, in the first edge section 410 the upper waveguide layer 240 is arranged in the growth direction 201 at the height of the active layer 230 in the central section 300.

Light generated in the active layer 230 in the central section 300 of the semiconductor structure 20 of the edge-emitting semiconductor laser 10 is guided in the central section 300 in the waveguide layers 220, 240 between the cladding layers 210, 250. In the first edge section 410, however, the light is guided at least partially in the upper cladding layer 250. The latter has an increased band gap compared to the waveguide layers 220, 240 so that the light guided in the first edge section 410 in the upper cladding layer 250 cannot be absorbed, or can be absorbed only to a small extent, in the first edge section 410. The first facet 400 and the first edge section 410, adjacent to the first facet 400, of the semiconductor structure 20 of the edge-emitting semiconductor laser 10 therefore form a nonabsorbing mirror.

The first facet 400 and/or the second facet 500 of the semiconductor structure 20 of the edge-emitting semiconductor laser 10 may have coatings (not represented in FIG. 1), which may be used for passivation and/or antireflection or to increase reflectivity. These coatings may, for example, be applied by evaporation, sputtering or CVD coating, and may, for example, comprise Al₂O₃, SiO₂, Si₃N₄, TiO₂, ZrO₂, Ta₂O₅, HfO₂, Si or other materials and combinations of these materials.

The layer sequence 200 may additionally comprise a contact layer (not represented in FIG. 1) above the upper cladding layer 250. Furthermore, a metallization (not represented in FIG. 1) used to electrically contact the semiconductor structure 20 of the edge-emitting semiconductor laser may be arranged on an upper side of the layer sequence 200. This metallization may extend over the central section 300 and the first edge section 410, although it may also be restricted to the central section 300.

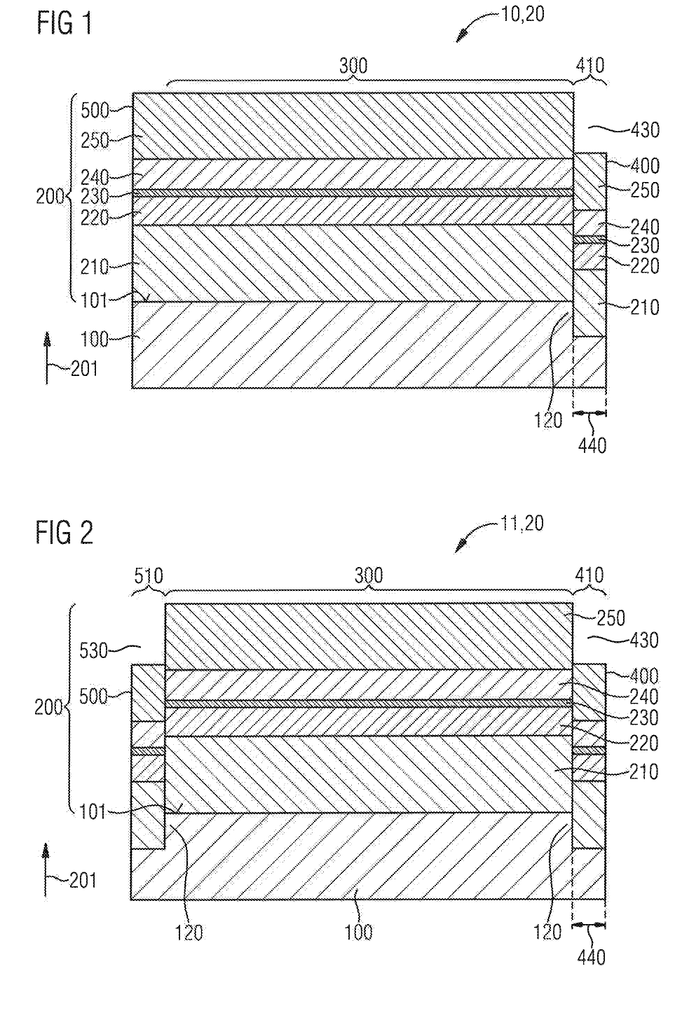

Further edge-emitting semiconductor lasers will be described below with the aid of FIGS. 2 to 8. The further edge-emitting semiconductor lasers respectively have major correspondences with the edge-emitting semiconductor laser 10 of FIG. 1. Only the differences of the further edge-emitting semiconductor lasers from the edge-emitting semiconductor laser 10 of FIG. 1 will therefore respectively be explained below. Components of the further edge-emitting semiconductor lasers that correspond to the components existing in the edge-emitting semiconductor laser 10 of FIG. 1 are provided with the same references in FIGS. 2 to 8 as in FIG. 1.

FIG. 2 shows a schematic sectional side view of the semiconductor structure 20 of an edge-emitting semiconductor laser 11 according to a second example. In the edge-emitting semiconductor laser 11, the semiconductor structure 20, in addition to the central section 300 and the first edge section 410 adjacent to the first facet 400, has a second edge section 510 adjacent to the second facet 500. In this case, a second offset 530 in the growth direction 201 is formed in the layer sequence 200 between the second edge section 510 and the central section 300.

The second offset 530 of the layer sequence 200 of the semiconductor structure 20 of the edge-emitting semiconductor laser 11, between the second edge section 510 and the central section 300, is configured such that the layers 210, 220, 230, 240, 250 of the layer sequence 200 lie lower in the growth direction 201 in the second edge section 510 than in the central section 300. In the second edge section 510, the upper cladding layer 250 is arranged in the growth direction 201 at the height of the active layer 230 in the central section 300. Light excited in the central section 300 of the semiconductor structure 20 and guided in the waveguide layers 220, 240 is therefore guided at least partially in the upper cladding layer 250 in the second edge section 510, and therefore cannot be absorbed in the second edge section 510, or can be absorbed only to a small extent in the second edge section 510. In the semiconductor structure 20 of the edge-emitting semiconductor laser 11, therefore, the second facet 500 and the second edge section 510, which is adjacent to the second facet 500, also form a nonabsorbing mirror.

During the epitaxial growth of the layer sequence 200 of the semiconductor structure 20 of the edge-emitting semiconductor laser 11, the second offset 530 has been produced by a step 120 formed between the second edge section 510 and the central section 300 on the upper side 101 of the substrate 100. In the semiconductor structure 20 of the edge-emitting semiconductor laser 11, the substrate 100 therefore respectively has a step 120 both at the boundary between the first edge section 410 and the central section 300 and at the boundary between the second edge section 510 and the central section 300.

The second edge section 510, adjacent to the second facet 500, and the second offset 530 may be configured mirror-symmetrically with respect to the first edge section 410, adjacent to the first facet 400, and the first offset 430. In this case, the width of the second edge section 510, i.e. the distance of the central section 300 from the second facet 500, corresponds to the width 440 of the first edge section 410. Furthermore, in this case, the size of the second offset 530 of the layer sequence 200 in the growth direction 201 in the second edge section 510 corresponds to the size of the first offset 430 of the layer sequence 200 in the first edge section 410.

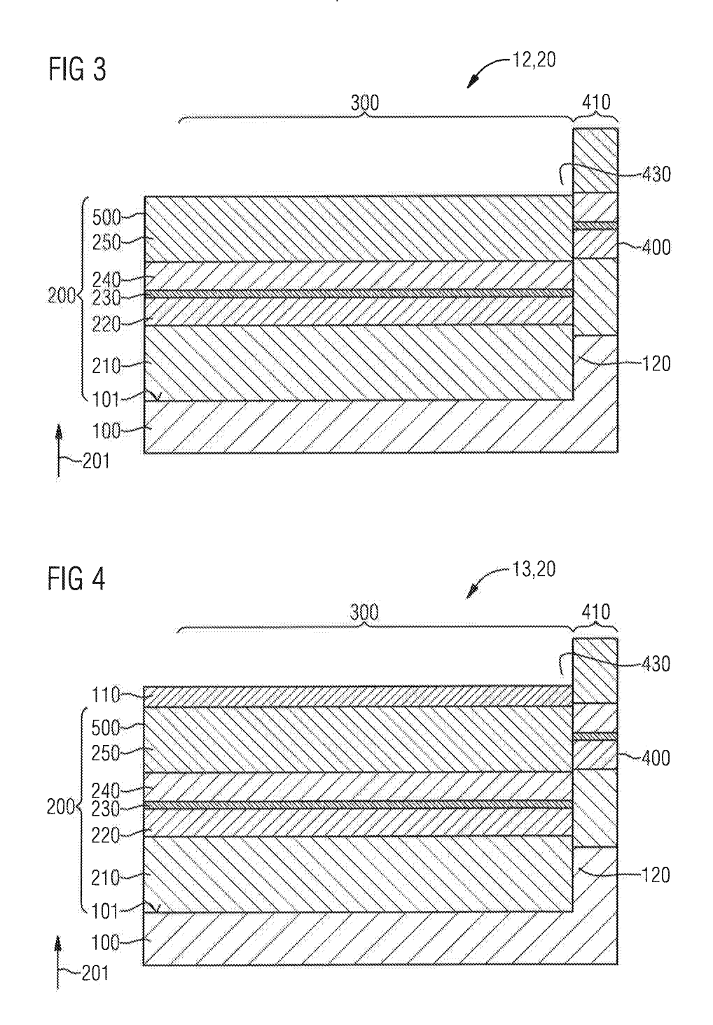

FIG. 3 shows a schematic sectional side view of the semiconductor structure 20 of an edge-emitting semiconductor laser 12 according to a third example. The edge-emitting semiconductor laser 12 differs from the edge-emitting semiconductor laser 10 of FIG. 1 in that the first offset 430 of the layer sequence 200 in the first edge section 410 is configured such that the layer sequence 200 lies higher in the growth direction 201 in the first edge section 410 than in the central section 300. In the first edge section 410, the lower cladding layer 210 of the layer sequence 200 therefore lies in the growth direction 201 at the height of the active layer 230 in the central section 300. As an alternative, in the first edge section 410, the lower waveguide layer 220 could also lie in the growth direction 201 at the height of the active layer 230 in the central section 300.

In the edge-emitting semiconductor laser 12, light excited in the active layer 230 in the central section 300 of the semiconductor structure 20 and guided in the waveguide layers 220, 240 is guided at least partially in the lower cladding layer 210 in the first edge section 410. The latter has an increased band gap compared to the waveguide layers 220, 240 so that absorption of light cannot take place, or can take place only to a small extent, in the first edge section 410. The first facet 400 and the first edge section 410, adjacent to the first facet 400, therefore also form a nonabsorbing mirror in the semiconductor structure 20 of the edge-emitting semiconductor laser 12.

In the semiconductor structure 20 of the edge-emitting semiconductor laser 12, the substrate 100 also has a step 120 on its upper side 101 between the central section 300 and the first edge section 410, which step is continued in the layer sequence 200 grown over the upper side 101 of the substrate 100 and causes the first offset 430. In the semiconductor structure 20 of the edge-emitting semiconductor laser 12, however, the step 120 on the upper side 101 of the substrate 100 is configured such that the upper side 101 of the substrate 100 lies higher in the growth direction 201 in the first edge section 410 than in the central section 300. This may have been achieved by a part of the substrate 100 having been removed before the epitaxial growth of the layer sequence 200 in the central section 300 of the substrate 100, for example, by an etching process, in particular a dry etching process.

The semiconductor structure 20 of the edge-emitting semiconductor laser 12 may, in a similar way to the semiconductor structure 20 of the edge-emitting semiconductor laser 11 of FIG. 2, also be configured with a second offset 530 in the second edge section 510, which is adjacent to the second facet 500 so that the second facet 500 and the second edge section 510, which is adjacent to the second facet 500, also form a nonabsorbing mirror. In this case, the second edge section 510 and the second offset 530 may, for example, be configured mirror-symmetrically with respect to the first edge section 410 and the first offset 430.

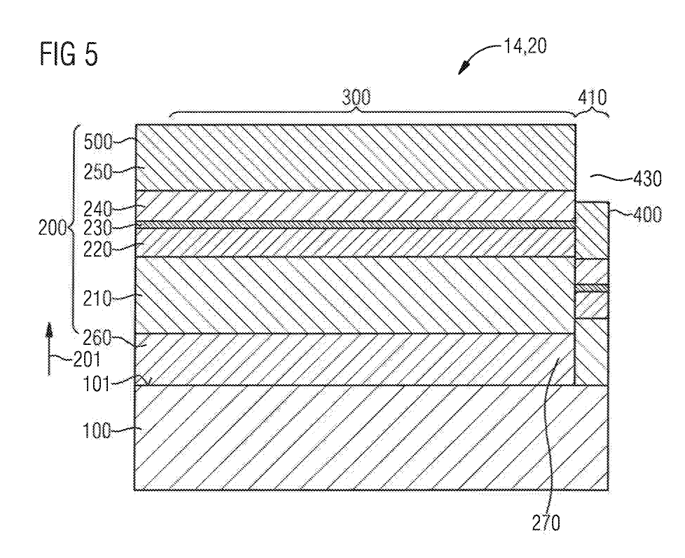

FIG. 4 shows a schematic sectional side view of the semiconductor structure 20 of an edge-emitting semiconductor laser 13 according to a fourth example. The semiconductor structure 20 of the edge-emitting semiconductor laser 13 is configured like the semiconductor structure 20 of the edge-emitting semiconductor laser 12 of FIG. 3.

In the edge-emitting semiconductor laser 13, an upper metallization 110 that electrically contacts the edge-emitting semiconductor laser 13 is arranged over the upper cladding layer 250 of the layer sequence 200. A contact layer (not represented in FIG. 4) could furthermore also be arranged between the upper cladding layer 250 and the upper metallization 110. The upper metallization 110 extends over the central section 300, but not over the first edge section 410 of the semiconductor structure 20. During operation of the edge-emitting semiconductor laser 13, therefore, electrical current is not conducted, or conducted only to a small extent, in the first edge section 410 through the layer sequence 200 of the semiconductor structure 20. The effect achieved by this is that light is not excited, or excited only to a small extent, in the first edge section 410 of the semiconductor structure 20.

If the semiconductor structure 20 of the edge-emitting semiconductor laser 13 is configured with a second offset 530 in the second edge section 510, which is adjacent to the second facet 500, then it is also possible, for example, for the upper metallization 110 not to extend over the second edge section 510.

FIG. 5 shows a schematic sectional side view of the semiconductor structure 20 of an edge-emitting semiconductor laser 14 according to a fifth example. In the semiconductor structure 20 of the edge-emitting semiconductor laser 14, the first offset 430 is configured in the layer sequence 200 between the first edge section 410 and the central section 300 such that the layer sequence 200 lies higher in the growth direction 201 in the central section 300 than in the first edge section 410.

In the semiconductor structure 20 of the edge-emitting semiconductor laser 14, however, the substrate 100 does not have a step on its upper side 101, but is configured in a planar fashion. Instead, in the semiconductor structure 20 of the edge-emitting semiconductor laser 14, the layer sequence 200 comprises an additional layer 260, which is arranged in sections between the upper side 101 of the substrate 100 and the lower cladding layer 210. In the example represented, this additional layer 260 is present only in the central section 300, but not in the first edge section 410 so that the additional layer 260 forms a step 270 at the boundary between the central section 300 and the first edge section 410. The step 270 continues in the layer sequence 200 grown epitaxially over the additional layer 260 and over the upper side 101 of the substrate 100 and, therefore, forms the first offset 430.

The additional layer 260 may initially have been applied onto the entire area, i.e. both in the central section 300 and in the first edge section 410, onto the upper side 101 of the substrate 100, for example, likewise by epitaxial growth, before the epitaxial growth of the further layers 210, 220, 230, 240, 250. The additional layer 260 may subsequently have been removed in the first edge section 410, for example, by an etching process in particular, for example, by a dry etching process or a wet chemical etching process. The remaining layers 210, 220, 230, 240, 250 of the layer sequence 200 have subsequently been grown.

It is possible to remove the additional layer 260 after application onto the entire area on the upper side 101 of the substrate 100 in the first edge section 410 not fully, but only partially so that the additional layer 260 subsequently has a greater height in the growth direction 201 in the central section 300 than in the first edge section 410.

It is also possible to configure the semiconductor structure 20 of the edge-emitting semiconductor laser 14 with a second offset 530 in the second edge section 510, which is adjacent to the second facet 500. To this end, the additional layer 260 is also fully or partially removed in the second edge section 510, before the remaining layers 210, 220, 230, 240, 250 of the layer sequence 200 are grown.

The additional layer 260 has doping with the same sign as the doping of the lower cladding layer 210, for example, n-doping. The additional layer 260 may comprise the same material as the lower cladding layer 210.

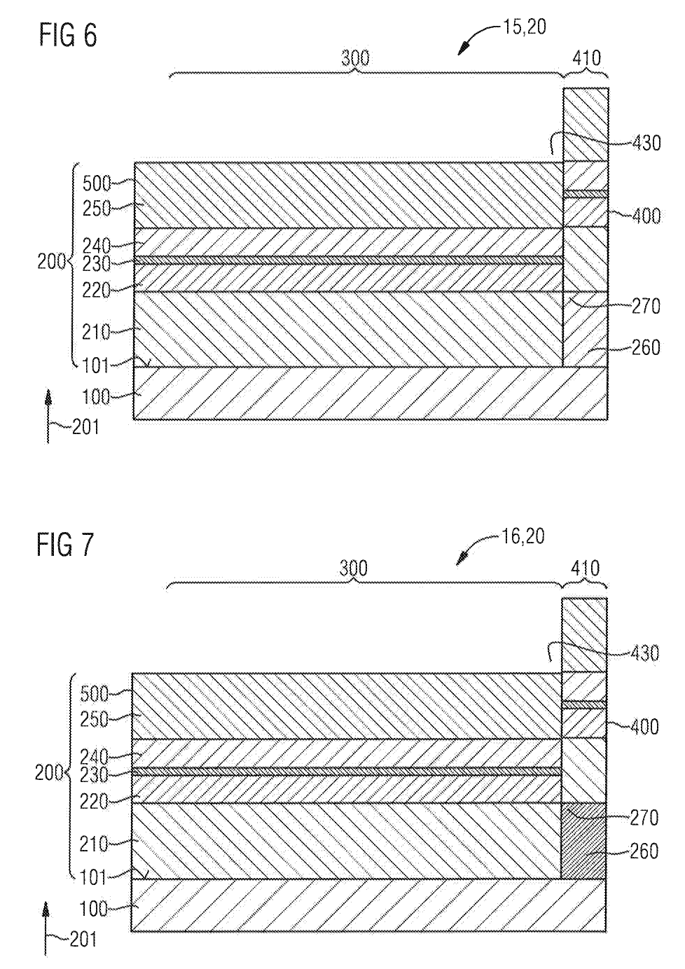

FIG. 6 shows a schematic sectional side view of the semiconductor structure 20 of an edge-emitting semiconductor laser 15 according to a sixth example. In the semiconductor structure 20 of the edge-emitting semiconductor laser 15, the upper side 101 of the substrate 100 is also configured in a planar fashion and without a step 120. Instead, the additional layer 260, which forms the step 270 that as the first offset 430 continues in the remaining layer sequence 200 of the semiconductor structure 20, is also present in sections in the semiconductor structure 20 of the edge-emitting semiconductor laser 15 between the upper side 101 of the substrate 100 and the lower cladding layer 210.

In the semiconductor structure 20 of the edge-emitting semiconductor laser 15, however, the additional layer 260 is present only in the first edge section 410, but not in the central section 300. The first offset 430 is therefore configured in the semiconductor structure 20 of the edge-emitting semiconductor laser 15 such that the layer sequence 200 lies higher in the growth direction 201 in the first edge section 410 than in the central section 300. If the semiconductor structure 20 of the edge-emitting semiconductor laser 15 is configured with a second offset 530 of the layer sequence 200 in the second edge section 510, which is adjacent to the second facet 500, then the additional layer 260 is also present in the second edge section 510.

During production of the semiconductor structure 20 of the edge-emitting semiconductor laser 15, the additional layer 260 may also initially be arranged over the entire area on the upper side 101 of the substrate 100 in the central section 300 and in the first edge section 410. The additional layer 260 is subsequently fully or partially removed in the central section 300.

In the semiconductor structure 20 of the edge-emitting semiconductor laser 15, the additional layer 260 also has doping with the same sign as the doping of the lower cladding layer 210, for example, n-doping. The additional layer 260 may, for example, comprise the same material as the lower cladding layer 210.

FIG. 7 shows a schematic sectional side view of the semiconductor structure 20 of an edge-emitting semiconductor laser 16 according to a seventh example. The semiconductor structure 20 of the edge-emitting semiconductor laser 16 is configured like the semiconductor structure 20 of the edge-emitting semiconductor laser 15. In the semiconductor structure 20 of the edge-emitting semiconductor laser 16, however, the additional layer 260 has either doping with the opposite sign compared to the lower cladding layer 210, i.e., for example, p-doping or comprises an insulating material. If the additional layer 260 comprises an insulating material, then the additional layer 260 may, for example, be configured as an undoped epitaxial layer, a CVD diamond layer or a dielectric layer.

In each case, it is expedient to apply the additional layer 260 by epitaxial growth and form it from the same material system as the remaining layer sequence 200. The effect achieved by this is that the layer sequence 200 is formed with few defects and in a low-stress manner. In this way, it is possible to substantially avoid an increase in leakage currents at the facets 400, 500 and an increase in the absorption at the facets 400, 500 so that high facet loading limits can be obtained. Furthermore, a minimization of an undesired fracture rate may be achieved by a low-stress layer sequence 200. Matching the crystal structure of the additional layer 260 to the crystal structure of the remaining layer sequence 200 may improve the fracture quality at the facets 400, 500 so that reduced facet losses and improved performance data can again be obtained.

During production of the semiconductor structure 20 of the edge-emitting semiconductor laser 16, the additional layer 260 may also initially be arranged over the entire area on the upper side 101 of the substrate 100 in the central section 300 and in the first edge section 410. The additional layer 260 is subsequently removed fully in the central section 300.

The effect achieved as a result of the additional layer 260 having doping with the opposite sign compared to the doping of the lower cladding layer 210, or comprising an insulating material, is that no current flow, or only a small current flow, takes place through the layer sequence 200 in the first edge section 410 during operation of the edge-emitting semiconductor laser 16. No light is therefore excited in the first edge section 410 of the semiconductor structure 20 of the edge-emitting semiconductor laser 16 so that the first edge section 410 is heated only to a small extent.

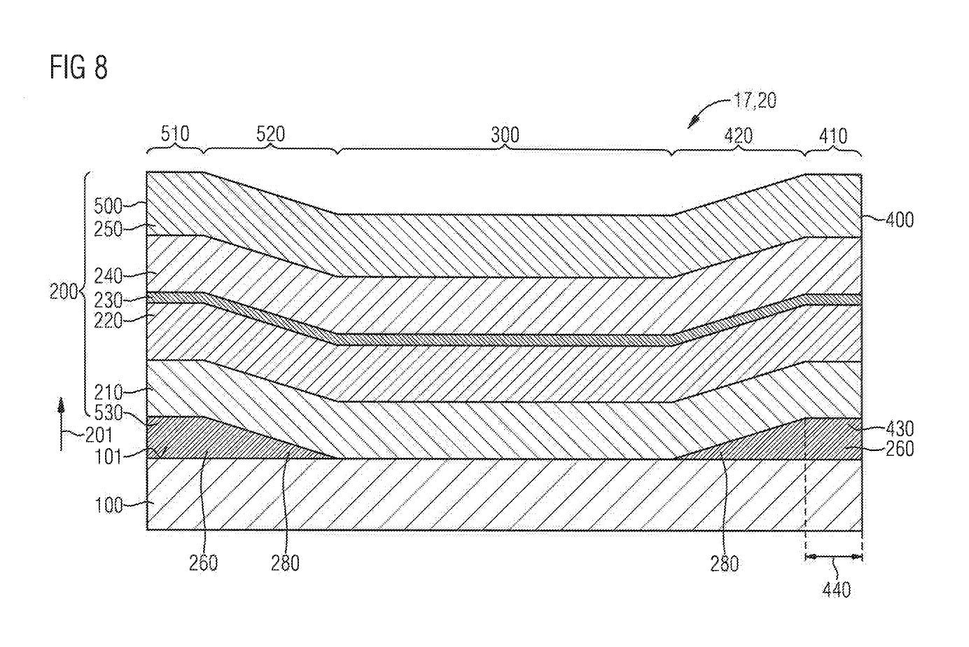

FIG. 8 shows a schematic sectional side view of the semiconductor structure 20 of an edge-emitting semiconductor laser 17 according to an eighth example. In the semiconductor structure 20 of the edge-emitting semiconductor laser 17, the layer sequence 200 has a first offset 430 in the first edge section 410, which is adjacent to the first facet 400, and a second offset 530 in the second edge section 510, which is adjacent to the second facet 500. The offsets 430, 530 are configured such that the layer sequence 200 is arranged lower in the growth direction 201 in the central section 300 than in the first edge section 410 and in the second edge section 510. It would, however, be possible in the semiconductor structure 20 of the edge-emitting semiconductor laser 17 to provide only the first offset 430 in the first edge section 410 and to omit the second offset 530 in the second edge section 510.

In the semiconductor structure 20 of the edge-emitting semiconductor laser 17, a first transition section 420 is formed between the first edge section 410 and the central section 300. Correspondingly, a second transition section 520 is also formed between the second edge section 510 and the central section 300. The individual layers 210, 220, 230, 240, 250 of the layer sequence 200 of the semiconductor structure 20 of the edge-emitting semiconductor laser 17 respectively continue continuously from the central section 300 through the first transition section 420 as far as the first edge section 410, and from the central section 300 through the second transition section 520 as far as the second edge section 510. In the transition sections 420, 520, the individual layers 210, 220, 230, 240, 250 of the layer sequence 200 are arranged not perpendicularly to the growth direction 201, but at an angle not equal to 90° with respect to the growth direction 201.

In the semiconductor structure 20 of the edge-emitting semiconductor laser 17, the substrate 100 does not have a step 120. Instead, the layer sequence 200 of the semiconductor structure 20 of the edge-emitting semiconductor laser 17 comprises an additional layer 260 arranged in the edge sections 410, 510 and in the transition sections 420, 520 between the upper side 101 of the substrate and the lower cladding layer 210. In the central section 300, the additional layer 260 is fully removed in the semiconductor structure 20 of the edge-emitting semiconductor laser 17. If the additional layer 260 is configured with doping, the sign of which corresponds to the doping of the lower cladding layer 210, then a part of the additional layer 260 can also be arranged in the central section 300 between the upper side 101 of the substrate 100 and the lower cladding layer 210. In this case, the parts of the additional layer 260 arranged in the edge sections 410, 510 would have a greater thickness in the growth direction 201 than the part of the additional layer 260 arranged in the central section 300.

In the transition sections 420, 520, the thickness of the additional layer 260 measured in the growth direction 201 continuously increases. In the transition sections 420, 520, the additional layer 260 therefore forms ramps 280 whose upper sides are not arranged parallel to the upper side 101 of the substrate 100. The upper sides of the ramps 280 have an angle with respect to the upper side 101 of the substrate 100, which may be 3° to 90°, in particular 10° to 88°, in particular 20° to 80°. In the semiconductor structure 20 of the edge-emitting semiconductor laser 17, the additional layer 260 therefore does not have a step. Instead, in the semiconductor structure 20 of the edge-emitting semiconductor laser 17, the additional layer 260 forms the ramp 280, along which the thickness of the additional layer 260 in the growth direction 201 varies continuously.

Alternatively, it is possible to omit the additional layer 260. Instead, the upper side 101 of the substrate 100 is lowered in the central section 300 so that the upper side 101 of the substrate 100 is arranged lower in the growth direction 201 in the central section 300 than in the edge sections 410, 510. In the transition sections 420, 520, the upper side 101 of the substrate 100 is chamfered such that the height of the upper side 101 of the substrate 100, measured in the growth direction 201, varies continuously between the central section 300 and the edge sections 410, 510. The upper side 101 of the substrate 100 therefore forms the ramp 280 in the transition sections 420, 520.

Alternatively, the additional layer 260 is configured such that it has a greater thickness in the growth direction 201 in the central section 300 than in the edge sections 410, 510. In the transition sections 420, 520, the thickness of the additional layer 260 varies continuously. In the layer sequence 200 subsequently grown epitaxially over the additional layer 260, the layers 210, 220, 230, 240, 250 then lie higher in the growth direction 201 in the central section 300 than in the edge sections 410, 510.

Alternatively, the additional layer 260 is omitted. Instead, the upper side 101 of the substrate 100 is structured such that the upper side 101 of the substrate 100 lies higher in the growth direction 201 in the central section 300 than in the edge sections 410, 510. In the transition sections 420, 520, the height of the upper side 101 of the substrate 100 again varies continuously. The layers 210, 220, 230, 240, 250 of the layer sequence 200 grown over the upper side 101 of the substrate 100 in this case also lie higher in the growth direction 201 in the central section 300 than in the edge sections 410, 510.

Alternatively, the layer sequence 200 lies higher in the growth direction 201 in the first edge section 410 than in the central section 300, while it lies lower in the growth direction 201 in the second edge section 510 than in the central section 300. In yet another example, the situation is reversed.

Our lasers and methods have been illustrated and described in more detail by the preferred examples. This disclosure is nevertheless not restricted to the examples disclosed. Rather, other variants may be derived herefrom by those skilled in the art without departing from the protective scope of the disclosure.

This application claims priority of DE 10 2015 104 184.7, the subject matter of which is incorporated herein by reference.

1.-9. (canceled)

10. An edge-emitting semiconductor laser comprising a semiconductor structure having a substrate and a layer sequence arranged over an upper side of the substrate and having layers lying above one another along a growth direction,
wherein a lower cladding layer, a lower waveguide layer, an active layer, an upper waveguide layer and an upper cladding layer follow one another in the layer sequence,
the semiconductor structure is laterally bounded by a first facet and a second facet,
the semiconductor structure has a central section and a first edge section adjacent to the first facet,
the layer sequence is offset relative to the central section in the growth direction in the first edge section such that, in the first edge section, one of the cladding layers or one of the waveguide layers is arranged in the growth direction at a height of the active layer in the central section,
the layer sequence comprises an epitaxially grown additional layer arranged between the upper side of the substrate and the lower cladding layer at least in the first edge section,
the additional layer is not arranged between the upper side of the substrate and the lower cladding layer in the central section, and
the additional layer is electrically insulating or has doping with the opposite sign to the lower cladding layer.

11. The edge-emitting semiconductor laser according to claim 10, wherein the semiconductor structure has a second edge section adjacent to the second facet, and
the layer sequence is offset relative to the central section in the growth direction in the second edge section.

12. The edge-emitting semiconductor laser according to claim 11, wherein the offset of the layer sequence in the second edge section corresponds to the offset of the layer sequence in the first edge section.

13. The edge-emitting semiconductor laser according to claim 10, wherein the layer sequence lies higher in the growth direction in the first edge section than in the central section.

14. The edge-emitting semiconductor laser according to claim 10, wherein the semiconductor structure has a first transition section between the central section and the first edge section, and
the layer sequence continues continuously between the central section, the first transition section and the first edge section.

15. The edge-emitting semiconductor laser according to claim 10, wherein the central section lies at a distance of 0.1 μm to 100 μm from the first facet.

16. The edge-emitting semiconductor laser according to claim 10, wherein a contact layer and an upper metallization are arranged over the layer sequence, and
the upper metallization is arranged only over the central section and not over the first edge section.

17. A method of producing an edge-emitting semiconductor laser comprising:
providing a substrate having an upper side;
arranging an additional layer on the upper side of the substrate by epitaxial growth;
removing a part of the additional layer in a central section to form, on an upper side of the substrate, a surface having a different height in the central section than in a first edge section;
depositing a layer sequence over the surface,
wherein deposition of the layer sequence comprises deposition of a lower cladding layer, a lower waveguide layer, an active layer, an upper waveguide layer and an upper cladding layer,
the additional layer is electrically insulating or has doping with the opposite sign to the lower cladding layer,
a height difference of the surface between the central section and the first edge section is dimensioned such that, in the first edge section, one of the cladding layers or one of the waveguide layers is arranged at the height of the active layer in the central section; and
fracturing the substrate and the layer sequence such that a first facet, to which the first edge section is adjacent, is formed.

18. The method according to claim 17, wherein removal of the additional layer is carried out by an etching method.
